(19) United States
(12) Patent Application Publication
(10) Pub. No.: US 2025/0331262 A1
(43) Pub. Date: Oct. 23, 2025

(54) SEMICONDUCTOR DIE AND METHOD OF MANUFACTURING THE SAME

(71) Applicant: Infineon Technologies AG, Neubiberg (DE)

(72) Inventors: Thomas GANNER, Krumpendorf am Wörthersee (AT); Philipp ROSS, München (DE); Michael HELL, Erlangen (DE); Andreas KORZENIETZ, Putzbrunn (DE); Thomas SÖLLRADL, Arnoldstein (AT); Dethard PETERS, Höchstadt (DE); Caspar LEENDERTZ, München (DE); Tobias WASSERMANN, Soest (DE)

(21) Appl. No.: 19/181,813

(22) Filed: Apr. 17, 2025

(30) Foreign Application Priority Data
Apr. 18, 2024 (DE) 102024203636.6

(51) Int. Cl. H10D 62/832; H10D 12/01; H10D 30/63; H10D 62/00; H10D 62/13; H10D 62/17; H10D 64/27

(52) U.S. Cl. CPC H10D 62/8325; H10D 12/031; H10D 30/637; H10D 62/01; H10D 62/151; H10D 62/378; H10D 64/529

(57) ABSTRACT

The present application relates to a semiconductor die, comprising a silicon carbide (SiC) semiconductor body comprising a first doping type region; a metallization on a first side of the SiC semiconductor body; an inorganic passivation layer system; a lateral edge of the inorganic passivation layer system arranged on the SiC semiconductor body, wherein the lateral edge of the inorganic passivation layer system is laterally offset inwards from a lateral edge of the SiC semiconductor body, the SiC semiconductor body being uncovered by the inorganic passivation layer system in an edge area, wherein a second doping type well is formed at the first side of the SiC semiconductor body in the first doping type region, the second doping type well extending from below the inorganic passivation layer system into the edge area.

### RELATED APPLICATION

This application claims priority to German Patent Application No. 102024203636.6, filed on Apr. 18, 2024, entitled “SEMICONDUCTOR DIE AND METHOD OF MANUFACTURING THE SAME”, which is incorporated by reference herein in its entirety.

### TECHNICAL FIELD

The present disclosure relates to a semiconductor die comprising a semiconductor body.

### BACKGROUND

In embodiments of this application, the semiconductor body is made of silicon carbide (SiC) which has a comparably wide band gap, e.g. compared to silicon. This can for instance be of interest for power semiconductor devices in high voltage and/or high current applications. In the semiconductor body, a device structure with a load terminal or terminals can be formed, for example a transistor structure having a source terminal and a drain terminal. For a wiring and contacting of the device structure, a metallization can be formed on the semiconductor body.

### SUMMARY

Examples of the present application are directed at an advantageous semiconductor die.

In an embodiment, a semiconductor die comprises a silicon carbide (SiC) semiconductor body, a metallization on a first side of the SiC semiconductor body, and an inorganic passivation layer system. A lateral edge of the inorganic passivation layer system may be arranged offset inwards from a lateral edge of the SiC semiconductor body. The SiC semiconductor body comprises a first doping type region, wherein a second doping type well may be formed at the first side of the SiC semiconductor body in the first doping type region.

The second doping type well may extend from below the inorganic passivation layer system into an edge area where the SiC semiconductor body is uncovered, i.e. not covered by the inorganic passivation layer system. In other words, the second doping type well may be arranged below the lateral edge of the inorganic passivation layer system; as seen in a vertical top view, the lateral edge of the inorganic passivation layer system may be arranged laterally within the second doping type well.

The second doping type well in the first doping type region may be depleted, for instance at least partially close to the surface (first side) of the semiconductor body, e.g. in a blocking state of a device formed in the die. Due to this depleted area or region at the first side of the SiC semiconductor body, less or no charge carriers/electrons may be available there. This can for instance reduce an oxidation risk, e.g. risk of a SiC oxidation in the edge area aside the inorganic passivation layer system (where the SiC semiconductor body may be exposed) or even below the inorganic passivation layer system. Such an oxidation might be triggered or driven by humidity, e.g. in combination with electrical fields. For instance at the lateral edge of the inorganic passivation layer system, which lies on the SiC semiconductor body, a SiC oxidation might introduce mechanical stress and cause a delamination risk. Depleting the semiconductor body locally at the first side may reduce the oxidation risk by removing the charge carriers which may be a prerequisite for one possible oxidation mechanism.

Further embodiments and features are provided in the dependent claims and throughout this disclosure. Therein, the individual features shall be disclosed independently of a specific claim category, the disclosure relates to apparatus and device aspects but also to method and use aspects. If for instance a die manufactured in a specific way is described, this is also a disclosure of a respective manufacturing process, and vice versa. In general words, embodiments of the present application aim at providing a second doping type well at a first side of a SiC semiconductor body in a first doping type region, e.g. where the first side of the SiC semiconductor body is exposed and/or where a lateral edge of an inorganic layer is arranged on the first side of the SiC semiconductor body.

Generally, when reference is made to an arrangement of a layer or lateral edge of the layer “on” another layer or entity, e.g. on the SiC semiconductor body, this does not necessarily imply an arrangement directly adjacent to this layer or entity. In other words, an additional layer may be arranged in between the inorganic passivation layer system and the first side of the SiC semiconductor body, e.g. an aluminum oxide layer. This additional layer may for instance serve as an adhesion promoter and/or etch stop layer. It can for instance have a thickness of not more than 30 nm, 20 nm or 15 nm, possible lower limits being for instance 3 nm or 5 nm.

The lateral edge of the additional layer may be arranged on the SiC semiconductor body, e.g. where the lateral edge of the inorganic passivation layer system is arranged. Alternatively, the additional layer may extend further, e.g. laterally outwards, than the inorganic passivation layer system. As an alternative to the additional layer below, however, the inorganic passivation layer system, i.e. the lateral edge thereof, may also be arranged directly on the SiC semiconductor body.

Generally, the SiC semiconductor body may comprise a SiC semiconductor substrate, for instance in combination with one or a plurality of epitaxial SiC layers thereon. That side of an uppermost epitaxial SiC layer, which faces away from the SiC substrate, may be the “first side” of the SiC semiconductor body. Vice versa, that side of the SiC substrate, which faces away from the epitaxial SiC layer or layers, may be the “second side” of the SiC semiconductor body. The “edge area” can for instance be arranged between a lateral edge of the SiC semiconductor body and the lateral edge of the inorganic passivation layer system.

The second doping type well is arranged “at the first side” of the SiC semiconductor body, which generally means closer to the first side than to the second side of the SiC semiconductor body. The second doping type well does not necessarily lie directly adjacent to the first side (i.e. touch the first side), instead it can also be slightly offset downwards (see FIG. 8 for illustration). In other words, an upper and of the second doping type well may be arranged at a distance from the first side, e.g. of not more than 5 μm, 4 μm, 3 μm, 2 μm or 1 μm, or it may lie in the first side of the SiC semiconductor body.

Independently of these details, the second doping type well may be embedded into the first doping type region, the first doping type region extending for instance below and, optionally, also aside the second doping type well (at least on one side thereof, see in detail below). The first doping type region can for instance be an epitaxial layer, wherein the second doping type well may be a local implantation into this epitaxial layer. In an active area of the SiC semiconductor body, where a device structure is formed, a drift region can be formed in the epitaxial layer. In other words, the first doping type region may be a low-doped (first doping type) epitaxial layer, e.g. having a lower doping concentration than a load terminal of the device, e.g. a drain region.

One of the first and second doping type is n-type, the other one being p-type. Between the first doping type region and the second doping type well, a pn-junction is formed. This pn-junction may extend in parallel to the first side of the SiC semiconductor body, e.g. apart from a lateral end of the second doping type well. As viewed for instance in a sectional plane perpendicular to a lateral edge of the SiC semiconductor body, a lateral extension of the second doping type well and pn-junction, thus, may be significantly larger than its vertical depth (e.g. at least 10×. 50× or 100×).

In an embodiment, a doping concentration of the first doping type region is smaller than a doping concentration of the second doping type well. The doping concentration of the second doping type well can for instance be at least 3×, 5×, 7×, 9× or 10× larger than the doping concentration of the first doping type region, possible upper limits being for example 500×, 200×, 100×, 80×, 50× or 20×. The doping concentration of the first doping type region may for instance be smaller than 2e16 cm⁻³ and/or the doping concentration of the second doping type well may be larger than 2e17 cm⁻³. In case of a second doping type well and/or a first doping type region having a concentration gradient in the vertical direction, the concentrations at the pn-junction are compared.

As viewed in a sectional plane perpendicular to the lateral edge of the SiC semiconductor body, the second doping type well may have an outer lateral end and an inner lateral end, wherein the inner lateral end is arranged at a larger distance from the lateral edge of the SiC semiconductor body than the outer lateral end. The inner lateral end of the second doping type well may be arranged below the inorganic passivation layer system, its outer lateral end being for instance arranged in the edge region. In an embodiment, the lateral edge of the inorganic passivation layer system has a smaller lateral distance from the inner lateral end than from the outer lateral end. In other words, the lateral edge of the inorganic passivation layer system is arranged closer to the inner lateral end than to the outer lateral end of the second doping type well.

Generally, “inner” and “outer” relate to the lateral position with respect to the respective lateral edge of the SiC semiconductor body, “outer” being more distant from and “inner” being closer to this lateral edge. Generally, when elements are discussed with respect to their relative position, these elements are for instance arranged on the same side of an active area of the semiconductor body or die, i.e. at the same lateral edge of the SiC semiconductor body. Therein, similar structures may be arranged at the other lateral edges of the SiC semiconductor body, e.g. enclose the active area as discussed in further detail below.

In an embodiment, the outer lateral end of the second doping type well is offset inwards from the lateral edge of the SiC semiconductor body. In other words, the outer lateral end of the inorganic passivation layer system is arranged at a distance from the outer lateral edge of the SiC semiconductor body. The first doping type region can for instance extend laterally between, the second doping type well being embedded in both lateral directions as viewed in a sectional plane perpendicular to the lateral edge of the SiC semiconductor body.

In an alternative embodiment, the second doping type well extends all the way to the lateral edge of the SiC semiconductor body. In other words, the second doping type well ends at the lateral edge of the SiC semiconductor body.

Generally, the lateral edge, e.g. outer lateral edge, of the inorganic passivation layer system may be arranged between the lateral edge of the SiC semiconductor body and an active area. In other words, the lateral edge of the inorganic passivation layer system may be arranged in an edge termination region. In the active area, a device structure may be formed in the SiC semiconductor body, comprising for instance a first load terminal arranged at the first side of the SiC semiconductor body. Additionally, the device structure may comprise a second load terminal, e.g. at a vertically opposite second side of the SiC semiconductor body. The device structure can for instance be a FET having a source terminal/region and a drain terminal/region in the SiC semiconductor body, e.g. the source region at the first side of the SiC semiconductor body and the drain region at the second side thereof.

In addition to the source region and the drain region, the device may comprise a body region to which a gate electrode capacitively couples. Additionally, a drift region may be arranged between the body region and the drain region, e.g. made of the same doping type but with a lower concentration than the drain region. The source region and drain region and, if present, drift region may be made of a first doping type, the body region made of a second doping type. In the illustrated embodiments, the first doping type is n-type and the second doping type is p-type.

In an embodiment, the second doping type well is electrically connected to a load terminal formed at the second side of the SiC semiconductor body, e.g. the drain terminal/region in case of the FET. This electrical connection may be formed via the lateral edge of the SiC semiconductor body, e.g. directly to the second doping type well reaching to the lateral edge or via an additional contact structure on the first side. Independently of these details, the second doping type well can thus be connected to a backside potential of the SiC semiconductor body, e.g. drain potential.

In an embodiment, a conductor line connected to the second doping type well is arranged in the edge area and extends along the lateral edge of the SiC semiconductor body. The conductor line can allow for a stable potential distribution in the second doping type well along the lateral edge of the SiC semiconductor body, e.g. also along its other lateral edges or around the active area as a whole. In general, the conductor line may be floating, e.g. offset inwards from the lateral edge of the SiC semiconductor body. Alternatively, however, it may reach to the lateral edge and be connected to the backside potential, e.g. drain potential.

In an embodiment, the semiconductor die comprises an insulating layer on the first side of the SiC semiconductor body. The insulating layer can for instance be arranged directly on the first side, namely adjacent to the SiC semiconductor body. It may serve as an interlayer dielectric, e.g. define a contact structure between a metallization above and the semiconductor body below. The insulating layer is not necessarily arranged directly below the metallization, i.e. another layer may be arranged between. Alternatively, however, the insulating layer can also be arranged directly below the metallization. Independently of these details, the insulating layer may comprise an oxide layer, for example a borophosphosilicate glas (BPSG) layer. In other words, the insulating layer may comprise a doped oxide layer, for example in addition to an undoped oxide layer. The insulating layer may for instance have a total thickness of at least 0.3 μm, e.g. at least 0.5 μm, and/or at most 3 μm.

A lateral edge of the insulating layer, e.g. outer lateral edge of the insulating layer, may be offset inwards from the lateral edge of the SiC semiconductor body and be covered by the inorganic passivation layer system. In other words, the inorganic passivation layer system may extend further outwards than the insulating layer, the lateral edge of the insulating layer is offset inwards from the lateral edge of the inorganic passivation layer system.

In an embodiment, the lateral edge of the insulating layer, i.e. the outer lateral edge, is offset inwards from the inner lateral end of the second doping type well. In other words, the second doping type well does not extend all the way to the lateral edge of the insulating layer. As viewed in a sectional plane perpendicular to the lateral edge of the SiC semiconductor body, the outer lateral edge of the insulating layer and the inner lateral end of the second doping type well may be arranged at a distance to each other (i.e. the inner lateral end of the second doping type well being arranged further outward).

As alternative to the inorganic passivation layer system covering the outer lateral edge of the insulating layer, an outer lateral edge of the inorganic passivation layer system may be arranged on the insulating layer. In other words, the insulating layer may extend further outwards than the inorganic passivation layer system (an outer lateral portion of the insulating layer being not covered by the inorganic passivation layer system). In this case, for example, the second doping type well may reach below the insulating layer. As viewed in a sectional plane perpendicular to the lateral edge of the SiC semiconductor body, the outer lateral edge of the insulating layer and the inner lateral end of the second doping type well may be arranged at a distance to each other, wherein the outer lateral edge of the insulating layer is arranged further outward.

In an embodiment, a channel stopper is formed laterally inside the second doping type well, e.g. laterally closer to the second doping type well than to an active area of the SiC semiconductor body. It may lie at a distance or directly adjacent to the second doping type well. The channel stopper may, like the second doping type well, be embedded into the first doping type region and have for instance a higher doping concentration than the first doping type region. The channel stopper may for instance reduce or prevent a formation of an inversion layer due to ions/charges at the interface. For illustration, assuming a p-doped second doping type well and a p-doped region or well of a field reduction structure (see in detail below), a p-MOSFET might be formed in between. For instance in case of a low n-doped drift region (first doping type region), e.g. even a comparably small net amount of ions/charges may form a conducting channel between these p-wells (resulting for instance in a leakage current, e.g. when the p-doped well is connected to drain potential).

In an embodiment, an electrical field reduction structure is formed laterally between the active area and the second doping type well. When a channel stopper is provided, the electrical field reduction structure may be arranged laterally inside of the channel stopper. The electrical field reduction structure may have a doping concentration which at least integrally decreases towards the lateral edge of the SiC semiconductor body, e.g. decreases continuously and/or in steps (stepwise). The electrical field reduction structure may lower or reduce an electrical field, which reaches up from the backside to the first side, towards the active area in which the device structure is arranged.

The electrical field reduction structure may comprise an inner doping well into which a plurality of laterally staggered doping rings are embedded. As viewed for instance in a sectional plane perpendicular to the lateral edge of the SiC semiconductor body, the doped rings are arranged consecutively; as viewed in a vertical top view, they may form rings one nested in the other. The inner doping well may be made of a second doping type, the doped rings being for instance made of the second doping type as well.

In an embodiment, a lateral distance between the lateral edge of the inorganic passivation layer system and an inner lateral end of the second doping type well is at least 1 μm and/or at most 200 μm, further upper limits being for instance 100 μm or 50 μm. In other words, the inner end of the second doping type well may be offset inwards by at least 1 μm and/or at most 200 μm (or at most 100 μm or 50 μm) from the lateral edge of the inorganic passivation layer system.

In an embodiment, the second doping type well extends to a depth from the first side of the SiC semiconductor body of at least 0.1 μm, further lower limits being for instance at least 0.2 μm or 0.3 μm. Upper limits may be at most 5 μm, 4 μm, 3 μm or 2 μm. In detail, the depth may be taken as a distance between the first side of the SiC semiconductor body and a lower end of the second doping type well.

In an embodiment, the first doping type region has a lower doping concentration in an upper portion at the first side of the SiC semiconductor body than in a lower portion. In other words, the doping concentration is reduced where the second doping type well is embedded, which can for instance help to increase or extend the depletion region into the first doping type region. The reduced doping concentration can, for example, be in a range of 1e16 cm⁻³ to 1e¹⁴ cm⁻³. The upper portion, in which the doping concentration is reduced, may for instance extend over a depth of around 1 μm.

In an embodiment, a shallow first doping type well is formed at the first side of the SiC semiconductor body in the second doping type well. The shallow first doping type well may reach up to the first side of the SiC semiconductor body, i.e. lie adjacent to the first side. Referring to a vertical depth of the second doping type well, the shallow first doping type well can for instance have a depth of 10% to 90% of the depth of the second doping type well.

In an embodiment, the second doping type well, as viewed in a vertical top view, forms a closed line around the active area. For instance in combination with the electrical field reduction structure discussed above, the closed line formed by the second doping type well may be arranged outside thereof, e.g. outside the doped rings nested one in the other.

In an embodiment, a method of manufacturing a semiconductor die is provided. It may comprise:
i) providing a silicon carbide (SiC) semiconductor body which has a first doping type region in at least an edge area at a lateral edge of the SiC semiconductor body;
ii) forming a second doping type well embedded into the first doping type region in the edge area;
iii) forming an inorganic passivation layer system which, as viewed in sectional plane perpendicular to the lateral edge of the SiC semiconductor body, covers an inner lateral end of second doping type well.

As to additional embodiments and features, reference is made to the disclosure as a whole.

In an embodiment, prior to step iii), an insulating layer is formed on the SiC semiconductor body, wherein a lateral edge of the insulating layer is offset inwards from an inner lateral end of second doping type well.

### BRIEF DESCRIPTION OF THE DRAWINGS

Below, the semiconductor die and method of manufacturing are explained in further detail by means of exemplary embodiments. Therein, the individual features can also be relevant in a different combination.

FIG. 1 shows a cross-sectional view of a semiconductor die comprising a SiC semiconductor body, a metallization and an inorganic passivation layer system;

FIG. 2 shows a detailed view of an inorganic passivation layer system on a SiC semiconductor body comprising a second doping type well;

FIG. 3 shows a detailed view of a different embodiment;

FIG. 4 shows a detailed view of a further embodiment;

FIG. 5 shows a detailed view of a further embodiment;

FIG. 6 shows a detailed view of a further embodiment;

FIG. 7 shows a detailed view of a further embodiment;

FIG. 8 shows a detailed view of a further embodiment;

FIG. 9 shows a schematic cross-section of a device formed in an active area of a semiconductor die;

FIG. 10 summarizes some manufacturing steps in a flow diagram:

FIG. 11 shows a cross-sectional view of a semiconductor die comprising a SiC semiconductor body, an insulating layer and a passivation system.

### DETAILED DESCRIPTION

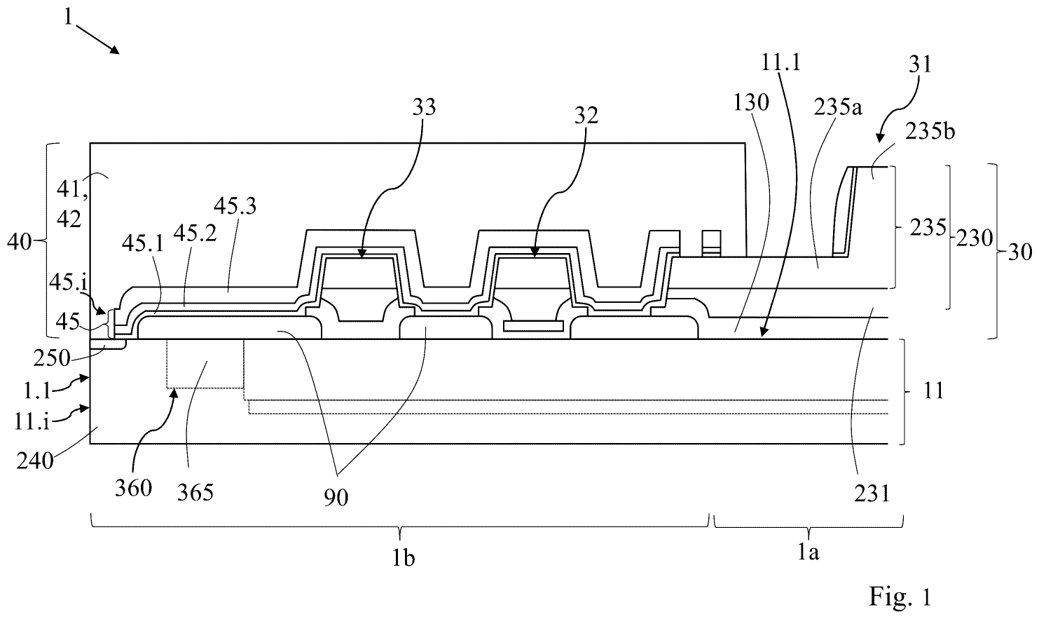

FIG. 1 shows a portion of a semiconductor die 1 in a vertical cross-section. The semiconductor die 1 comprises a silicon carbide (SIC) semiconductor body 11. On a first side 11.1 of the SiC semiconductor body 11, an insulating layer 90 is arranged. Further, a metallization 30 is formed on the SiC semiconductor body 11, which comprises a barrier layer system 130. On the barrier layer system 130, a copper layer system 230 is arranged, which in the example shown comprises a sputter-deposited copper layer 231 and a bath-deposited copper layer system 235 with a first bath-deposited copper layer 235a and a second bath-deposited copper layer 235b.

In detail, the cross-sectional view of FIG. 1 lies at a lateral edge 1.1 of the die 1, wherein an inactive area 1bis arranged laterally between the lateral edge 1.1 of the die 1 and an active area 1a shown on the right in FIG. 1. In the active area 1a, transistor device cells may be arranged (see in detail below). In the active area 1a, a load pad 31 may be formed in the metallization 30, for example a source pad connected to a source terminal of the device or device cells. In the inactive area 1b, a gate runner 32 and/or a source runner 33, each extending along the active area 1a, may be formed in the metallization 30.

On the metallization 30, a passivation system 40 is arranged, which in the example shown comprises an inorganic passivation layer system 45 and an organic layer 41, e.g. imide layer, on the inorganic passivation layer system 45. However, the organic layer 41 as shown is optional and may be omitted. In alternative embodiments, it can be provided on the inorganic passivation layer system 45 but lie laterally flush therewith, i.e. not extend laterally further than the inorganic passivation layer system 45. In this case, the organic layer 41 can be used as a mask for structuring the inorganic passivation layer system 45 during manufacturing and remain on the ready-made die.

The inorganic passivation layer system 45 shown comprises a first silicon nitride layer 45.1, an undoped silicon oxide layer 45.2 directly on the first silicon nitride layer 45.1, and a second silicon nitride layer 45.3 directly on the undoped silicon oxide layer 45.2. The passivation system 40 covers the gate runner 32 and source runner 33 and covers also the insulating layer 90 made of doped oxide (e.g. borophosphosilicate glass, BPSG).

Optionally, an aluminum oxide layer may be arranged below the inorganic passivation layer system 45, which is not shown here.

In the example shown, a lateral edge 45.i of the inorganic passivation layer system 45 is arranged laterally aside the insulating layer 90 on the first side 11.1 of the SiC semiconductor body. The SiC semiconductor body 11 comprises a first doping type region 240 in which a drift region can be formed in the active area 1a of the SiC semiconductor body 11. The first doping type region 240 is lightly doped, i.e. lightly n-doped in the example shown. At the first side 11.1 a second doping type well 250 is embedded into the first doping type region 240, i.e. a p-well in the example shown.

In this and the following figures, the layers 45.1-45.3 of the inorganic passivation layer system 45 are shown flush at the lateral edge 45.i. Alternatively, there may be a lateral offset between the layers 45.1-45.3, e.g. the undoped silicon oxide layer 45.2 protruding slightly outwards. In case of such an offset, the lateral edge 45.i of the inorganic passivation layer system 45 is defined by the lateral edge of the outwardly protruding layer

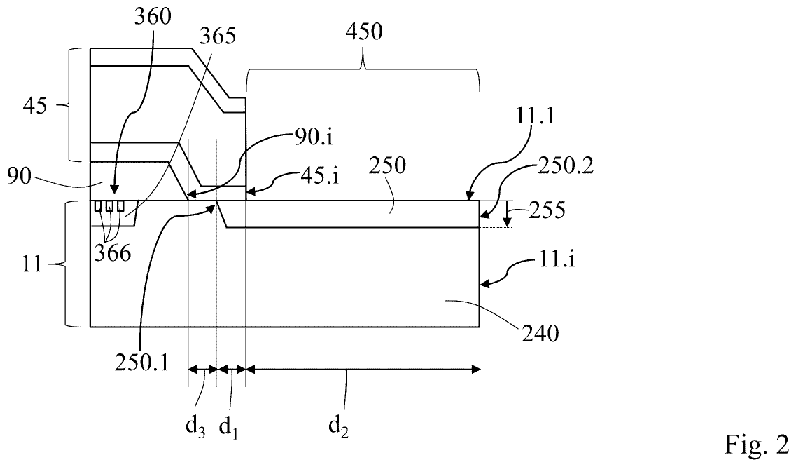

FIG. 2 illustrates an edge area 450 at the lateral edge 11.i of the SiC semiconductor body 11 in further detail (in comparison to FIG. 1, the view is mirrored horizontally). In this embodiment, the second doping type well 250 (e.g. p-well) extends laterally from below the inorganic passivation layer system 45 into the edge area 450 and all the way to the lateral edge 11.i of the SiC semiconductor body 11 (the sectional plane of this view lies perpendicular to this lateral edge 11.i). An outer lateral end 250.2 of the second doping type well 250 lies adjacent to the lateral edge 11.i of the SiC semiconductor body 11.

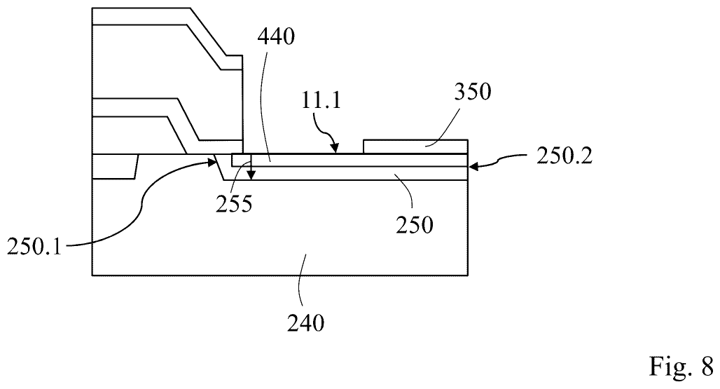

Vertically, the second doping type well 250 reaches up to the first side 11.1 of the SiC semiconductor body 11, i.e. lies adjacent to the first side 11.i (as to an alternative, reference is made to FIG. 8). In the embodiment shown, the second doping type well 250 extends to a vertical depth 255 of around 1 μm.

An inner lateral end 250.1 of the second doping type well 250 is arranged below the inorganic passivation layer system 45, wherein a distance d₁ between the inner lateral end 250.1 and the lateral edge 45.i of the inorganic passivation layer system 45 may be smaller than a distance d₂ between the lateral edge 45.i and the lateral edge 11.i of the SiC semiconductor body 11. The distance di may be between 1-50 μm. The second doping type well 250 does not extend below the insulating layer 90, its inner lateral end 250.1 may be arranged at a distance d₃ between 1-50 μm from an outer lateral edge 90.i of the insulating layer 90.

Laterally inside of the second doping type well 250, below the insulating layer 90, an electrical field reduction structure 360 is formed in the SiC semiconductor body 11. It comprises an inner doping well 365 into which a plurality of laterally staggered doped rings 366 are embedded, so that a doping concentration decreases stepwise towards the lateral edge 11.i of the SiC semiconductor body 11.

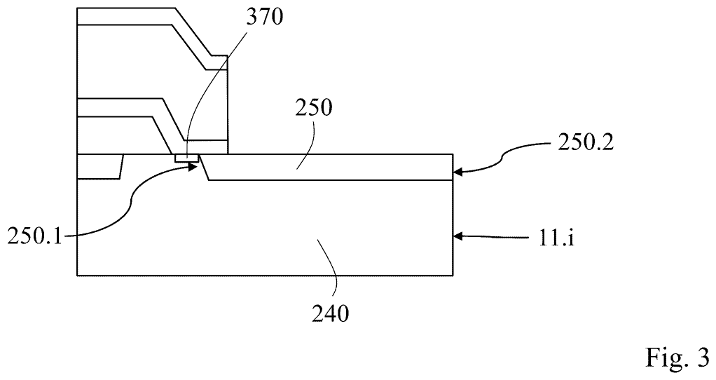

In the embodiment of FIG. 3, the second doping type well 250 has basically the same setup as in FIG. 2. Generally, in this disclosure, the like reference numerals indicate the like parts or parts having the like function, and reference is made to the description of the respectively other figures as well. The following description highlights mainly the differences to the embodiments described above. In FIG. 3, a channel stopper 370 is additionally formed laterally inside of the second doping type well 250. In this example, the channel stopper 370 is a n-doped region.

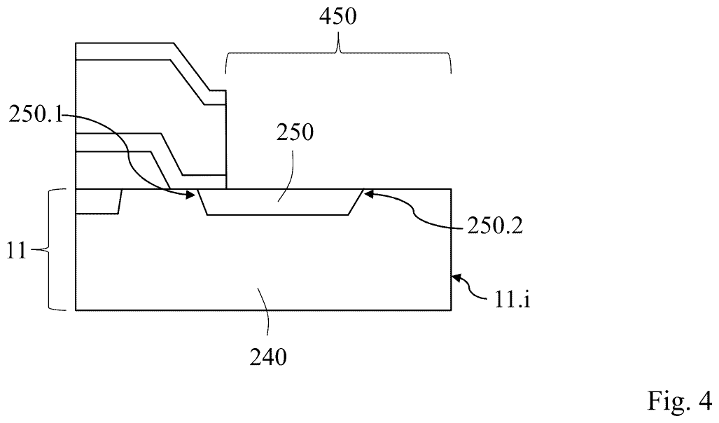

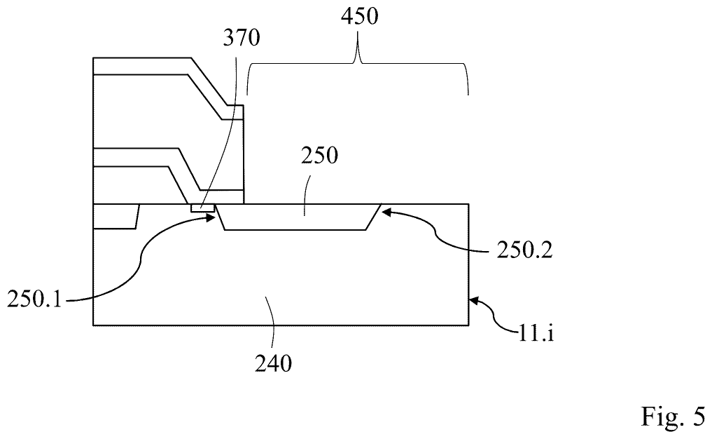

In the embodiment of FIG. 4, the second doping type well 250 does not extend all the way to the lateral edge 11.i of the SiC semiconductor body 11. Instead, the outer lateral end 250.2 of the second doping type well 250 is offset inwards, i.e. spaced from the lateral edge 11.i. This applies also for the embodiment of FIG. 5, wherein in contrast to FIG. 4 a channel stopper 370 is arranged laterally inside of the second doping type well 250 (see the remarks on FIG. 3).

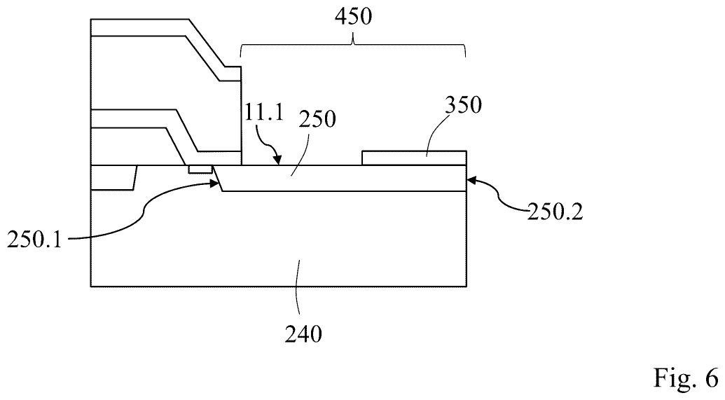

The second doping type well 250 shown in the embodiment of FIG. 6 corresponds to the one shown in FIG. 2. In addition, a conductor line 350 is formed on the first side 11.1 of the SiC semiconductor body 11 in the edge area 450. The conductor line 350 extends along the lateral edge 11.i of the SiC semiconductor body 11 (perpendicularly to the drawing plane), it can for instance be formed in a lowermost layer of the metallization 30. In the example shown, it lies adjacent to the lateral edge 11.i of the SiC semiconductor body 11, alternatively it can be offset inwards.

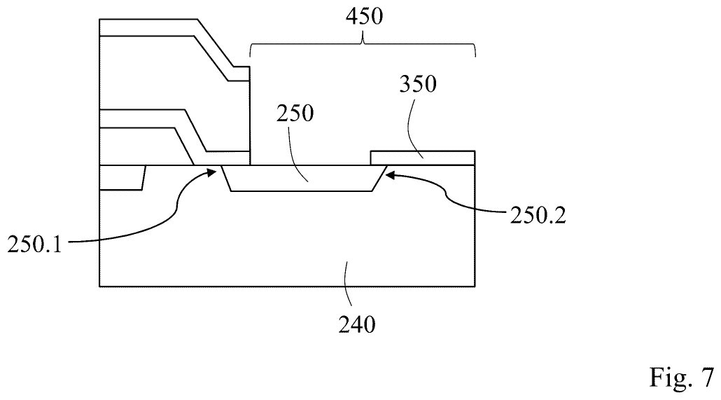

The second doping type well 250 of the embodiment shown in FIG. 7 corresponds to the one shown in FIG. 4, wherein a conductor line 350 as explained with reference to FIG. 6 is formed in the edge area 450. Optionally, a channel stopper can be formed laterally inside of the second doping type well 250 (not shown here, see FIG. 5 in comparison).

Generally, the second doping type well 250 may be connected to a backside potential via the lateral edge 11.i of the SiC semiconductor body 11, e.g. directly (see FIGS. 2, 3 and 6) or via the conductor line 350 as shown in FIG. 7.

FIG. 8 shows an alternative embodiment, in which the second doping type well 250 does not reach up to the first side 11.1 of the SiC semiconductor body 11. Instead, a shallow first doping type well 440 is formed there, which is a n-well in the example shown. It may have a depth of around 1 μm, the second doping type well extending to a vertical depth 255 of around 2 μm, for example.

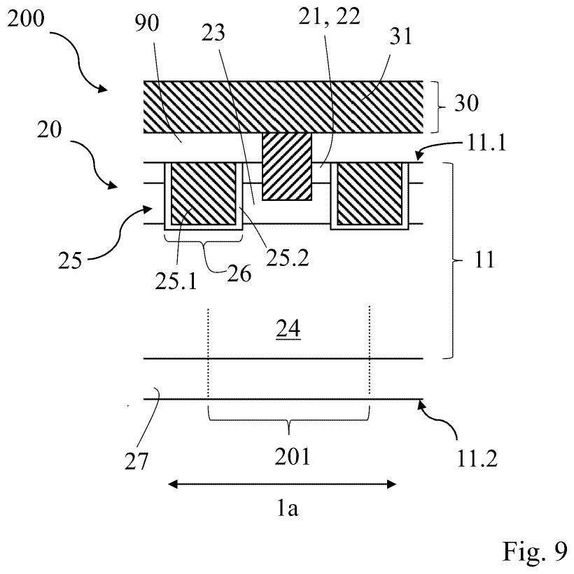

FIG. 9 illustrates a possible device 200 and device structure 20 formed in the active area 1a of the die 1, e.g. below the load pad 31 (see FIG. 1 for comparison). In the SiC semiconductor body 11, a load terminal 21 is formed at the first side 11.1, which is a source region 22 in the example shown. At the vertically opposite second side 11.2, a drain region 27 is arranged, wherein a body region 23 disposed below the source region 22 and a drift region 24 is arranged between the body region 23 and the drain region 27.

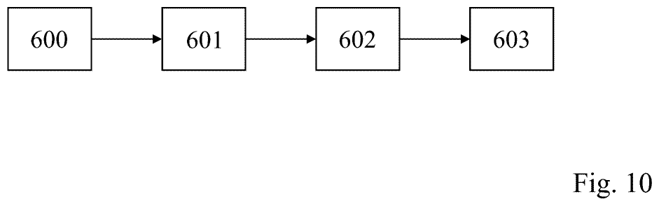

As illustrated in a flow diagram in FIG. 10, a method of manufacturing a semiconductor die may comprise providing 600 a SiC semiconductor body, forming 601 a second doping type well in the semiconductor body, forming 602 an insulating layer on the SiC semiconductor body and forming 603 and inorganic passivation layer system.

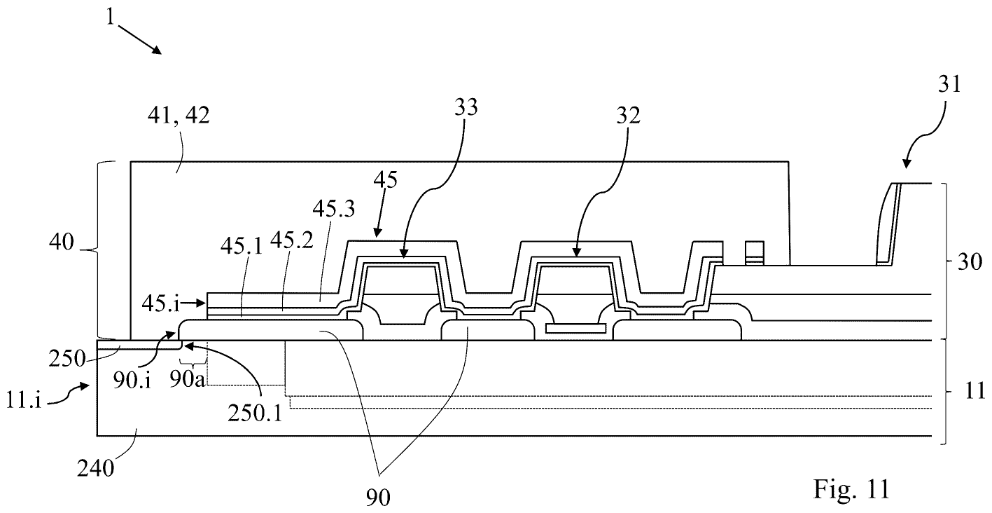

FIG. 11 shows an embodiment which differs partly from the one discussed with reference to FIG. 1. Also in this case, an insulating layer 90, a metallization 30 and a passivation system 40 are arranged on the first side 11.1 of the SiC semiconductor body 11 (see the description above for further details). In contrast to FIG. 1, the outer lateral edge 45.i of the inorganic passivation layer system 45 is not arranged aside the insulating layer 90, but on the insulating layer 90. Consequently, a portion 90a of the insulating layer 90 aside the outer lateral edge 45.i of the inorganic passivation layer system 45, i.e. between the outer lateral edge 45.i of the inorganic passivation layer system 45 and the outer lateral edge 90.i of the insulating layer 90, is not covered by the inorganic passivation layer system 45.

The second doping type region 250 reaches below the insulating layer 90, the inner lateral end 250.1 of the second doping type well 250 arranged below the insulating layer 90. As to possible design variants, reference is made to FIGS. 2-8.

1. A semiconductor die, comprising:
a silicon carbide (SiC) semiconductor body comprising a first doping type region;
a metallization on a first side of the SiC semiconductor body; and
an inorganic passivation layer system,
wherein a lateral edge of the inorganic passivation layer system is arranged on the SiC semiconductor body,
wherein the lateral edge of the inorganic passivation layer system is laterally offset inwards from a lateral edge of the SiC semiconductor body, the SiC semiconductor body being uncovered by the inorganic passivation layer system in an edge area,
wherein a second doping type well is formed at the first side of the SiC semiconductor body in the first doping type region,
wherein the second doping type well extends from below the inorganic passivation layer system into the edge area.

2. The semiconductor die of claim 1, wherein a doping concentration of the first doping type region is smaller than a doping concentration of the second doping type well.

3. The semiconductor die of claim 1, wherein the second doping type well has an inner lateral end below the inorganic passivation layer system and an outer lateral end in the edge area, wherein the lateral edge of the inorganic passivation layer system, as viewed in a sectional plane perpendicular to the lateral edge of the SiC semiconductor body, has a smaller lateral distance from the inner lateral end than from the outer lateral end.

4. The semiconductor die of claim 1, wherein the second doping type well extends from below the inorganic passivation layer system to an outer lateral end which is offset inwards from the lateral edge of the SiC semiconductor body.

5. The semiconductor die of claim 1, wherein the second doping type well extends from below the inorganic passivation layer system to the lateral edge of the SiC semiconductor body.

6. The semiconductor die of claim 1, wherein a device structure is formed in the SiC semiconductor body, which has a load terminal at a second side of the SiC semiconductor body vertically opposite to the first side, the second doping type well being electrically connected to the load terminal at the second side of the SiC semiconductor body via the lateral edge of the SiC semiconductor body.

7. The semiconductor die of claim 1, wherein a conductor line is arranged in the edge area, which extends along the lateral edge of the SiC semiconductor body and is electrically connected to the second doping type well.

8. The semiconductor die of claim 1, comprising:
an insulating layer on the first side of the SiC semiconductor body below the metallization,
wherein a lateral edge of the insulating layer is offset inwards from the lateral edge of the SiC semiconductor body and covered by the inorganic passivation layer system.

9. The semiconductor die of claim 8, wherein the lateral edge of the insulating layer is offset inwards from an inner lateral end of the second doping type well.

10. The semiconductor die of claim 1, wherein a channel stopper is formed laterally inside of the second doping type well, the channel stopper embedded into the first doping type region and having a higher doping concentration than the first doping type region.

11. The semiconductor die of claim 1, wherein an electrical field reduction structure is formed laterally between an active area and the second doping type well, the electrical field reduction structure having a doping concentration which at least integrally decreases towards the lateral edge of the SiC semiconductor body.

12. The semiconductor die of claim 11, wherein the electrical field reduction structure comprises an inner doping well into which a plurality of laterally staggered doped rings are embedded, wherein the inner doping well is covered by an insulating layer.

13. The semiconductor die of claim 1, wherein the second doping type well has an inner lateral end below the inorganic passivation layer system, wherein a lateral distance between the inner lateral end of the second doping type well and the lateral edge of the inorganic passivation layer system, as viewed in a sectional plane perpendicular to the lateral edge of the SiC semiconductor body, is at least one of at least 1 μm or at most 50 μm.

14. The semiconductor die of claim 1, wherein the second doping type well, as viewed in a sectional plane perpendicular to the lateral edge of the SiC semiconductor body, extends to a depth from the first side of SiC semiconductor body of at least one of at least 0.1 μm or at most 5 μm.

15. The semiconductor die of claim 1, wherein the first doping type region has a lower doping concentration in an upper portion at the first side of the SiC semiconductor body than in a lower portion.

16. The semiconductor die of claim 1, wherein a shallow first doping type well is formed at the first side of the SiC semiconductor body in the second doping type well.

17. The semiconductor die of claim 1, wherein a device structure is formed in an active area of the SiC semiconductor body, wherein the second doping type well, as viewed in a vertical top view, forms a closed line around the active area.

18. A method of manufacturing a semiconductor die, comprising:
providing a silicon carbide (SiC) semiconductor body which has a first doping type region in at least an edge area at a lateral edge of the SiC semiconductor body;
forming a second doping type well embedded into the first doping type region in the edge area; and
forming an inorganic passivation layer system which, as viewed in sectional plane perpendicular to the lateral edge of the SiC semiconductor body, covers an inner lateral end of second doping type well.

19. The method of claim 18, comprising, prior to forming the inorganic passivation layer system, forming an insulating layer on the SiC semiconductor body, a lateral edge of the insulating layer being offset inwards from an inner lateral end of the second doping type well.

20. A semiconductor die, comprising:
a silicon carbide (SiC) semiconductor body comprising a first doping type region;
a metallization on a first side of the SiC semiconductor body; and
an inorganic passivation layer system on or above the metallization,
wherein a lateral edge of the inorganic passivation layer system is arranged on the SiC semiconductor body,
wherein the lateral edge of the inorganic passivation layer system is laterally offset inwards from a lateral edge of the SiC semiconductor body, the SiC semiconductor body being uncovered by the inorganic passivation layer system in an edge area,
wherein a second doping type well is formed at the first side of the SiC semiconductor body in the first doping type region,
wherein the second doping type well extends from below the inorganic passivation layer system into the edge area.
